(19) United States
(12) Patent Application Publication
(10) Pub. No.: US 2026/0338852 A1
(43) Pub. Date: Oct. 29, 2026

(54) LOW FREQUENCY ACCELERATED LIFE TEST

(71) Applicant: Texas Instruments Incorporated, Dallas, TX (US)

(72) Inventors: Thomas Landon, JR., Plano, TX (US); Siraj Akhtar, Richardson, TX (US)

(21) Appl. No.: 19/314,517

(22) Filed: Aug. 29, 2025

Related U.S. Application Data
(60) Provisional application No. 63/792,978, filed on Apr. 23, 2025.

(51) Int. Cl. G01R 31/26

(52) U.S. Cl. CPC G01R 31/2642

(57) ABSTRACT

A test method includes heating a first device under test with a first transistor to a first temperature, sweeping a transistor bias point of the first transistor along a load line at a sweep frequency that is less than an operating frequency of the first device under test for multiple cycles at the first temperature until a first time at which a transistor performance parameter reaches a threshold, heating a second device under test with a second transistor to a different second temperature, sweeping a transistor bias point of the second transistor along the load line at the sweep frequency for multiple cycles at the second temperature until a second time at which the transistor performance parameter reaches the threshold, and determining a transistor lifetime based on the first and second times.

### REFERENCE TO RELATED APPLICATION

This application claims priority to and benefit of U.S. Provisional Patent Application Serial No. 63/792,978, filed on Apr. 23, 2025, and titled “Reliability Test for High Frequency Transistors”, the contents of which is hereby fully incorporated by reference.

### BACKGROUND

Electronic device long term reliability can be expressed in terms of expected lifetime, such as mean time to failure (MTTF). Determining a value that accurately represents expected lifetime for high frequency switching transistors can be costly, difficult and time consuming. Accelerated life tests elevate the device’s temperature to speed up lifetime determination. Devices designed for high frequency operation (e.g., radio frequencies (RF) on the order of GHz) can be life tested with the device transistor or transistors operating at the rated frequency, sometimes referred to as radio frequency accelerated life testing (RFALT). However, RFALT and other high frequency accelerated life testing is complex, time-consuming and requires expensive test equipment. Direct-current accelerated life testing (DCALT) can be done at a DC transistor operating point with less expensive test equipment, but DCALT is less accurate and may not accurately replicate all possible failure mechanisms of a transistor designed for operation at high frequencies.

### SUMMARY

In one aspect, a test method includes heating a first device under test with a first transistor to a first temperature, sweeping a transistor bias point of the first transistor along a load line at a sweep frequency that is less than an operating frequency of the first device under test for multiple cycles at the first temperature until a first time at which a transistor performance parameter reaches a threshold, heating a second device under test with a second transistor to a different second temperature, sweeping a transistor bias point of the second transistor along the load line at the sweep frequency for multiple cycles at the second temperature until a second time at which the transistor performance parameter reaches the threshold, and determining a transistor lifetime based on the first and second times.

In another aspect, a system includes first and second voltage sources, a heat source and a controller. The first voltage source has a first voltage output electrically coupled to a transistor gate of a device under test installed in a socket, the second voltage source has a second voltage output electrically coupled to a transistor drain of the device under test, and the heat source is operatively coupled to provide heat to the socket to heat the device under test. The controller is configured to control the heat source to heat a device under test with a transistor to a target temperature, and to control the first and second voltage sources to sweep a transistor bias point of the first transistor along a load line at a sweep frequency that is less than an operating frequency of the device under test for multiple cycles at the target temperature until a transistor performance parameter reaches a threshold.

### BRIEF DESCRIPTION OF THE DRAWINGS

FIG. 1 is a flow diagram of a method according to one aspect.

FIG. 2 is a life test system diagram according to another aspect.

FIG. 3 is a graph of an example class B constant power dissipation load line and a corresponding staircase load line.

FIG. 4 is a graph of an example class A constant power dissipation load line and a corresponding staircase load line.

FIG. 5 is a graph of junction temperature as a function of failure time for a transistor.

FIG. 6 is a graph of failure time as a function of temperature for different transistor failure mechanisms.

FIG. 7 is a graph of efficiency and peak power load lines for a class B Doherty power amplifier.

### DETAILED DESCRIPTION

In the drawings, like reference numerals refer to like elements throughout, and the various features are not necessarily drawn to scale. Also, the term "couple" or "couples" includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms "including", "includes", "having", "has", "with", or variants thereof are intended to be inclusive in a manner similar to the term "comprising", and thus should be interpreted to mean "including, but not limited to". Unless otherwise stated, “about,” “approximately,” or “substantially” preceding a value means +/- 10 percent of the stated value.

One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, etc., for ease of description in connection with a particular drawing, where such are not to be construed as limiting with respect to the claims. Various disclosed systems, devices and methods of the present disclosure may be beneficially applied to manufactured electronic apparatus such as an integrated circuit. While such examples may be expected to provide various improvements, no particular result is a requirement of the present disclosure unless explicitly recited in a particular claim.

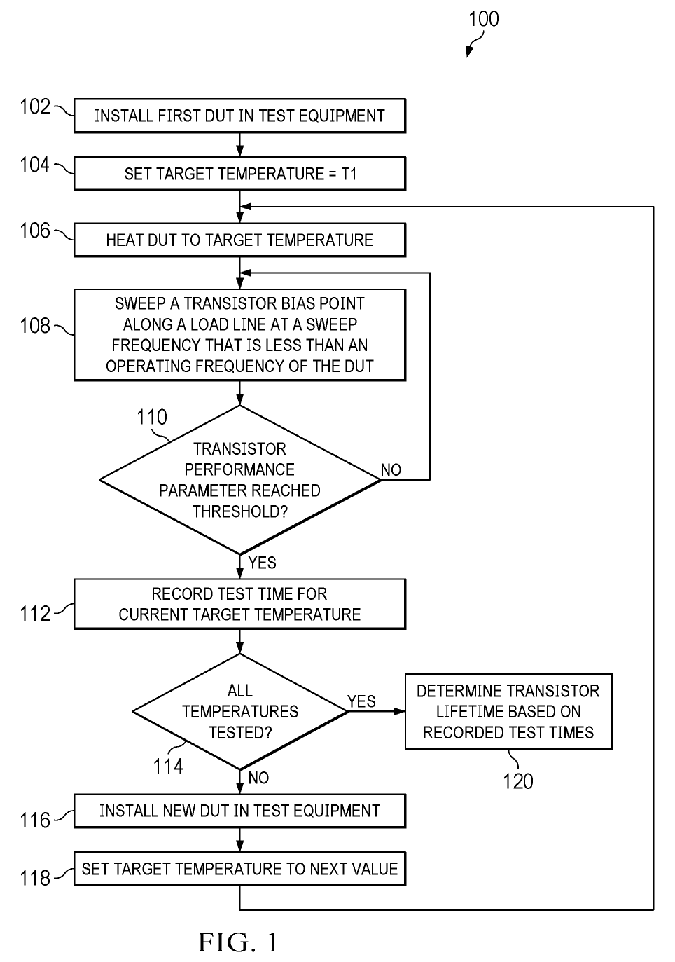

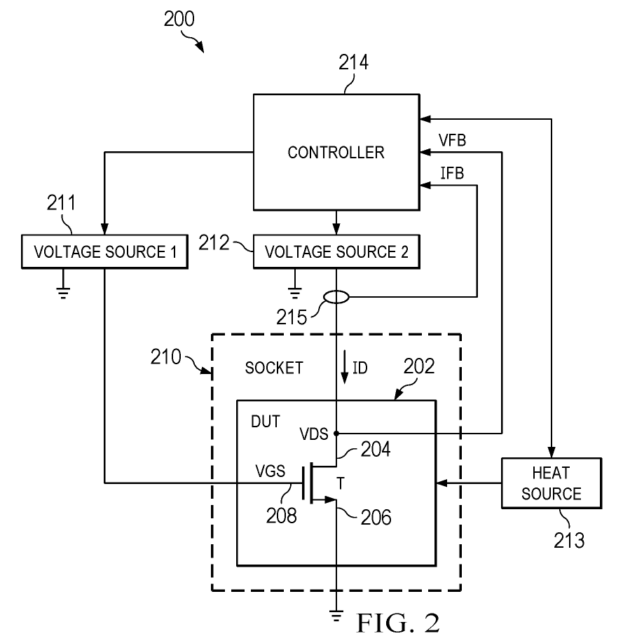

Referring initially to FIGS. 1 and 2, FIG. 1 shows a method 100 that provides cost effective life estimation for an electronic device. The example method 100 provides low frequency accelerated life test (LFALT) operation of a tested device and can be implemented using low-cost programmable test equipment without the excessive expense associated with RFALT systems. The LFALT of the method 100 can be performed in a suitable test system by control programming to make selective adjustments to an operating point of a tested device to accurately evaluate multiple failure mechanisms at elevated device operating temperatures.

At 102 in FIG. 1, a first electronic device under test (DUT) is installed in test equipment of a life test system. FIG. 2 shows an example test system 200, having an electronic device under test (DUT) 202 installed in a socket 210 for accelerated life testing according to an implementation of the method 100 of FIG. 1. The example method 100 of FIG. 1 is illustrated and described further hereinafter in connection with the example test system 200 of FIG. 2 in an example life test for evaluating mean time to failure (MTTF) of an electronic device having a transistor T. As shown in FIG. 2, the example transistor T is a field effect transistor (FET) with a drain 204, a source 206, and a gate 208. In the illustrated example, the socket 210 includes terminals that are electrically coupled with pins or other terminals of the tested DUT 202 when the DUT 202 is installed in the socket 210, allowing testing of multiple instances of the DUT 202 for evaluating MTTF,

The test system 200 of FIG. 2 includes respective first and second voltage sources 211 and 212, a heat source 213, and a controller 214 programmed or otherwise configured by program instructions to implement various functions described herein. In one example, the controller 214 and the voltage sources 211 and 212 are implemented as a source measurement unit (SMU) having power supplies, an electronic load to provide a load to the tested transistor T, one or more digital multimeters (DMMs). The first voltage source 211 has a first voltage output electrically coupled by the socket 210 to the transistor gate 208 of a DUT, and the voltage provided at the first voltage output of the voltage source 211 controls a gate voltage VGS of the transistor T. The second voltage source 212 has a second voltage output electrically coupled by the socket 210 to the transistor drain 204 of the DUT 202 in order to control a drain voltage VDS of the transistor T. The heat source 213 is operatively coupled to the socket 210 in order to provide heat to the socket 210 to heat the DUT 202.

In operation, the transistor T of the DUT 202 conducts a drain current ID through the drain terminal 204, and the gate voltage VGS provided by the first voltage source 211 to the gate terminal 208 controls the drain current ID. The system 200 includes a current sensor 215 configured to sense the drain current ID of the transistor T. The current sensor 215 provides a current feedback signal IFB to the controller 214 (e.g., to a DMM implemented by the controller 214). The current feedback signal IFB represents the drain current ID of the transistor T. The socket 210 also provides a drain voltage feedback signal VFB to the controller 214 (e.g., to a second DMM), and the feedback signal VFB represents the drain voltage VDS of the transistor T. During life testing, the controller 214 monitors the feedback signals IFB and VFB to evaluate the operation of the transistor T.

The system 200 is used to test two or more equivalent instances of the DUT 202 until the transistor performance reaches a threshold level, for example, representing device performance that indicates a predetermined amount of degradation. In one example, two or more DUTs 202 are provided having equivalent form and function (e.g., two or more production units, prototypes, etc.). The method 100 is used to evaluate a first DUT 202 operated at a first temperature T1 until the device’s performance indicates the predetermined amount of degradation. Thereafter a second DUT 202 is tested at a different second temperature T2 until the predetermined amount of degradation is observed. The method 100 can be implemented to test one or more further DUTs 202 in similar fashion and corresponding different temperatures.

At 104 in FIG. 1, with the first DUT 202 installed in the socket 210, the controller 214 sets a target temperature to the first temperature T1. At 106 in FIG. 1, the controller 214 operates the heat source 213 in order to heat the DUT 202 to the target first temperature T1. In one example, the heat source 213 operates to regulate the DUT temperature at or around the target temperature T1, and the target temperature can be correlated through suitable device modeling to a junction temperature of the transistor T of the DUT 202. In this manner, the junction temperature and/or the target temperature may be used during subsequent evaluation to plot a curve of degradation time as a function of temperature in order to determine a transistor lifetime based on recorded test times of two or more DUTs 202 (e.g., at 120 in FIG. 1).

The controller 214 is configured to control the heat source 213 to heat 106 the DUT 202 to the target temperature T1 while sweeping a transistor bias point at 108 in FIG. 1. In one example, the bias point is represented as the transistor drain current ID and the transistor drain voltage VDS. In one implementation, the transistor drain current ID is controlled by the transistor gate voltage VGS, and the load line represents the transistor drain current (ID) as a function of the transistor drain voltage (VDS) and the transistor gate voltage (VGS).

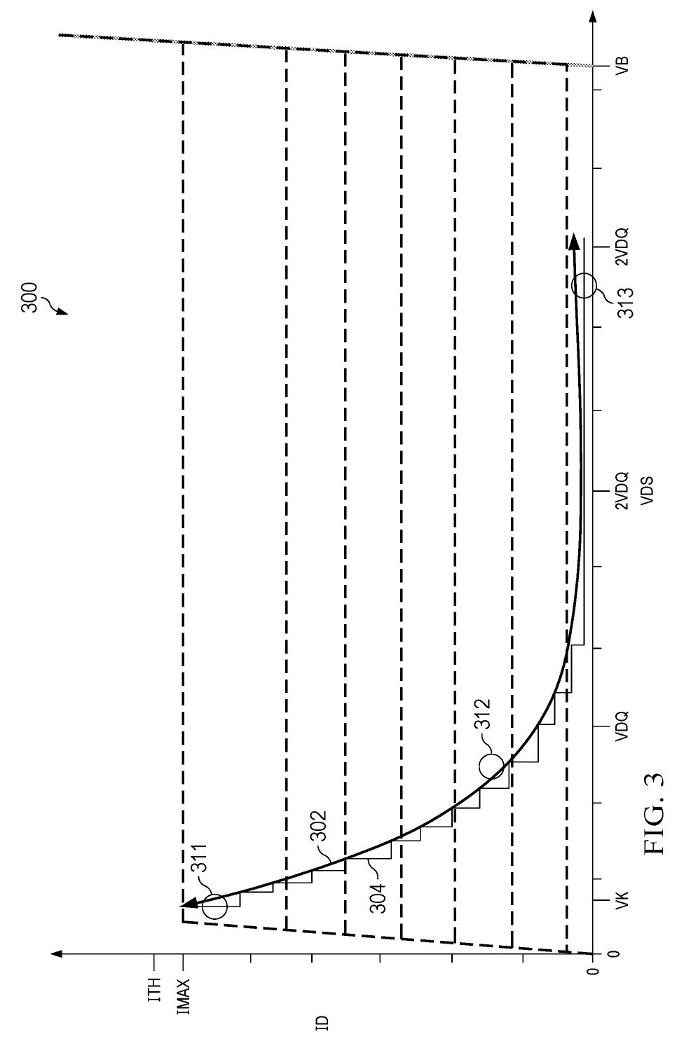

FIG. 3 shows a graph 300 with curves illustrating an example class B constant power dissipation load line 302 and a corresponding staircase load line 304 for an example power amplifier module DUT 202. The load lines 302 and 304 correspond to operation of the DUT 202 with respect to the drain current ID and the drain voltage VDS. As shown in FIG. 3, the vertical axis indicates a maximum transistor drain current IMAX, as well as a drain current threshold ITH. The horizontal axis of the graph 300 shows an example knee voltage value VK, and the transistor drain current ID initially rises as the drain current ID increases from 0 and reaches a peak at IMAX which corresponds to the knee voltage VK. Increasing drain voltage VDS along the horizontal axis reduces the drain current ID in a nonlinear fashion and the drain current remains at a non-zero value until a breakdown voltage VB. The horizontal axis in the graph 300 also indicates class and voltage values VDQ, 2VDQ and 3VDQ between the knee voltage VK and the breakdown voltage VB. The change in the drain current IDS in one implementation results from changes or adjustments in both the drain voltage VDS and the gate voltage VGS of the device. In FIG. 3, the different family of Ids curves (dashed lines) correspond to different VGS values. In order to change IDS, both VDS and VGS and being changed to mimic the approximate loadline (304).

During life testing in one example, the controller 214 is configured to control the respective first and second voltage sources 211 and 212 to sweep the transistor bias point (e.g., ID, VDS) of the first transistor T along the load line 302 at a sweep frequency at 108 in FIG. 1 for multiple cycles at the target temperature T1 until the transistor performance parameter ID reaches the threshold ITH. In this example, the sweeping at 108 includes adjusting the gate voltage VGS of the transistor T and adjusting the drain voltage VDS of the transistor T. Each sweep includes transitioning in one direction along the load line 302 and then back along the load line 302. In the illustrated example, the class B power amplifier load line 302 in FIG. 3 extends from approximately the drain current maximum IMAX at approximately the knee voltage VK to a significantly lowered drain current ID at a drain voltage VDS that is approximately equal to 2VDQ, although not a requirement of all possible implementations. In other examples, the endpoints of the load line 302 can be set to different values.

The controller 214 is configured to implement the sweep frequency significantly less than the rated operating frequency of the DUT 202. This advantageously allows use of lower cost test system equipment, for example, with programmable voltage sources 211 and 212 that can be programmatically adjusted by the controller 214 to implement multiple cycles of sweeps along the load line 302. In one example, the sweep frequency is 1 kHz or more and 1 MHz or less. In this or another example, the sweep frequency is less than 0.01 times the operating frequency of the first DUT 202 (e.g., more than two orders of magnitude below the rated operating frequency of the DUT 202).

For example, a class B power amplifier module DUT 202 having a gallium nitride transistor T may be designed for a rated operating frequency of 1 GHz or more. Accelerated life testing at that high rated operating frequency would be time-consuming, complex and require expensive test equipment of the system. Temperature controlled low frequency accelerated life testing at a sweep frequency of two or more orders of magnitude (e.g., 1 MHz or less) advantageously allows the use of programmable test equipment (e.g., the voltage sources 211 and 212) which can be operated by the controller 214 with incremental and/or continuous adjustment of the gate voltage VGS and the drain voltage VDS to track the load line 302 or the staircase load line 304 facilitates low cost expeditious accelerated life testing of the DUT 202.

The controller 214 can be configured to operate the voltage sources 211 and 212 to provide continuous adjustment of the gate voltage VGS and the drain voltage VDS while monitoring the feedback signals IFB and VFB to sweep the transistor operating point along the load line 302. In another example, the load line 304 can be used for sweeping the transistor operating point at 108, which has a staircase shape as shown in FIG. 3. In one implementation, the controller 214 can alternately adjust the first and second voltage sources 211 and 212 to implement a staircase load line 304 using any suitable in current values. In other examples, combinations of continuous load line and staircase load line sweeping can be implemented by the controller 214. During sweeping at 108 in FIG. 1, the controller 214 implements the sweep frequency that is less than the rated operating frequency of the DUT 202.

At 110 in FIG. 1, the controller 214 determines whether a transistor performance parameter has reached a threshold, such as Idsat dropping to a set threshold due to device wear or degradation. If the threshold has not been reached (NO at 110), the operating point sweeping continues at 108. The operating point sweeping at 108 for the first DUT 202 in one example continues for multiple cycles at the first temperature T1 until a first time TIME1 at which the transistor performance parameter (e.g., drain current ID) reaches the threshold ITH (YES at 110 in FIG. 1). In the illustrated example, the threshold current ITH is set to a value that is slightly lower than the maximum rated drain current IMAX (e.g., Idsat decreasing approximately 10 %). In other examples, different thresholds and/or transistor performance parameters can be used. In certain implementations, multiple transistor performance parameters and associated thresholds can be evaluated based on feedback signals from the tested DUT 202, and the controller 214 can be configured to terminate life tests sweeping at 110 for the first DUT 202 one or more of the evaluated performance parameters reaches the corresponding threshold, such as decreasing by a given percentage.

In the illustrated example, once the transistor performance parameter reaches the threshold (YES at 110), the method 100 continues at 112 in FIG. 1, and the controller 214 records the test time TIME1 for the current target temperature T1, for example, by storing in a memory of the controller 214. The controller 214 determines at 114 in FIG. 1 whether all target temperatures have been tested. In order to determine the transistor lifetime, at least two DUTs 202 are evaluated. In the illustrated example, the controller 214 determines that a second test is needed of a second DUT 202 (NO at 114 in FIG. 1).

At 116 in FIG. 1, a new DUT 202 is installed in the socket 210 of the test system 200. At 118, the controller 214 sets the target temperature to a second temperature T2 that is different than the first temperature T1. The method 100 then returns to 106, where the controller 214 operates the heat source 213 to heat the DUT 202 to the target second temperature T2. At 108, the controller 214 operates the voltage sources 211 and 212 to sweep the transistor bias point of the second transistor T along the load line 302 (and/or 304) at the sweep frequency for multiple cycles at the second temperature T2. The controller 214 evaluates the feedback signals IFB and VFB at 110 to determine whether the transistor performance parameter (e.g., ID) has reached the threshold (e.g., ITH).

Once the transistor performance parameter has reached the threshold (YES at 110 in FIG. 1) for the second tested DUT 202, the controller 214 records the test time TIME2 for the current target temperature T2, for example, by storing in the controller memory. The method 100 can continue for evaluation of further DUTs 202 in similar fashion at further different target temperatures. Once all temperatures have been tested (YES at 114 in FIG. 1), the method precedes to 120 where a transistor lifetime is determined based on the respective first and second times TIME1 and TIME2 and on the corresponding first and second temperatures T1 and T2 (as well as any further time and temperature data pairs corresponding to additionally evaluated DUTs 202).

In certain examples, the load lines 302 and 304 provide a constant power dissipation for the transistor T of the tested DUTs 202. This beneficially facilitates approximately constant junction temperature of the transistor T during accelerated life testing. In the illustrated examples, the times T1 and T2 are both higher than the rated operating temperature of the DUT 202, although not a requirement of all possible implementations. Elevated operating temperatures facilitate acceleration of the life test, and the test temperatures can be selected according to various practical and theoretical considerations based on a given DUT design.

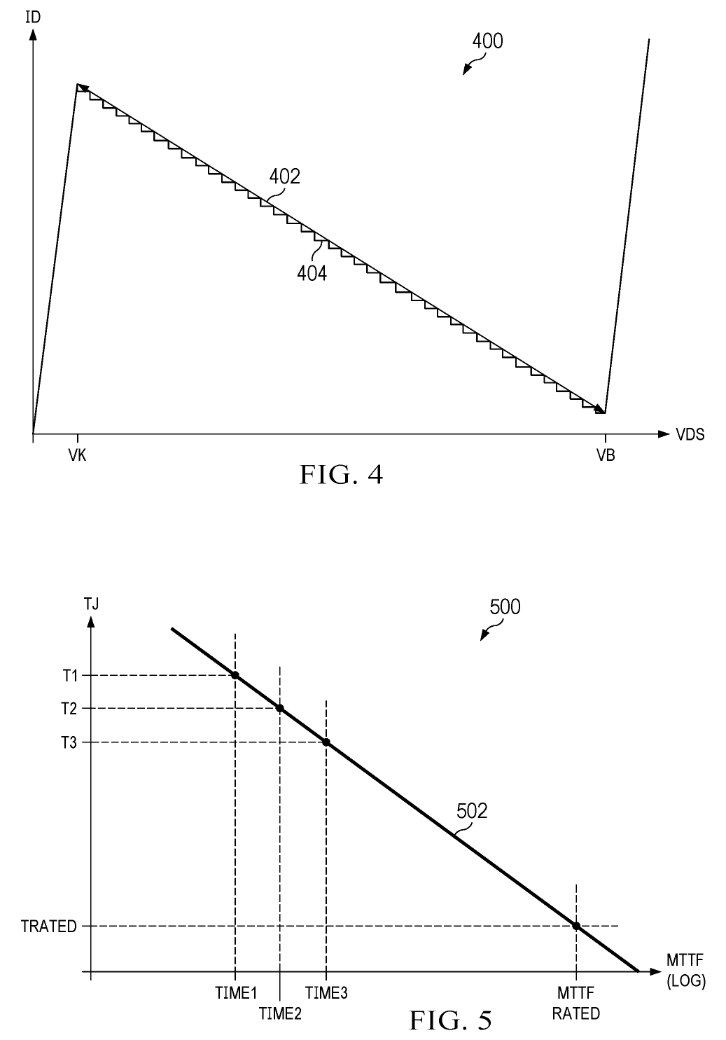

Referring also to FIG. 4, the example load lines 302 and 304 represent a class of an amplifier circuit of the device under test 202, for example, class B power amplifiers. FIG. 4 shows a graph 400 that illustrates another example, including an approximately linear load line 402 and a corresponding staircase load line 404 corresponding to a class A power amplifier DUT 202. Other amplifier class-based load lines can be used to test amplifier DUTs 202 having power amplifiers with different architectures and corresponding amplifier classes (not shown).

Referring also to FIG. 5, in one example, the transistor lifetime is determined graphically at 120 in FIG. 1 by an Arrhenius plot based on the recorded test times (e.g., TIME1 and TIME2) and on the corresponding first and second temperatures T1 and T2. Any suitable curve fitting and/or extrapolation techniques can be used at 120. FIG. 5 shows a graph 500 of DUT junction temperature TJ as a function of mean time to failure (MTTF) for a transistor T and a corresponding DUT 202. In this example, the tested DUT 202 has a rated maximum operating temperature TRATED, and three DUTs 202 were tested at different corresponding respective first, second and third temperatures T1, T2 and T3 as shown on the vertical axis of the graph 500. The accelerated life testing of the corresponding DUTs 202 resulted in corresponding respective first, second and third test times TIME1, TIME2 and TIME3 as indicated on the horizontal axis of the graph 500. In this particular example, the graph 500 can be constructed using a logarithmic horizontal axis for MTTF, although the logarithmic relationship of temperature and time is not a requirement of all possible implementations. The determination at 120 in FIG. 1 of the transistor lifetime in one example includes fitting a curve 502 and FIG. 5 to the three plotted data points (T1, TIME1; T2, TIME2; T3, TIME3) corresponding to the respective first, second, and third tested DUTs 202, for example, using any suitable numeric curve fitting algorithm more technique, to provide a linear curve 502. The curve 502 is extrapolated from the test data points to the rated maximum operating temperature TRATED of the DUT 202, and the corresponding horizontal axis MTTF value is determined at 120 as the rated mean time to failure for the DUT 202.

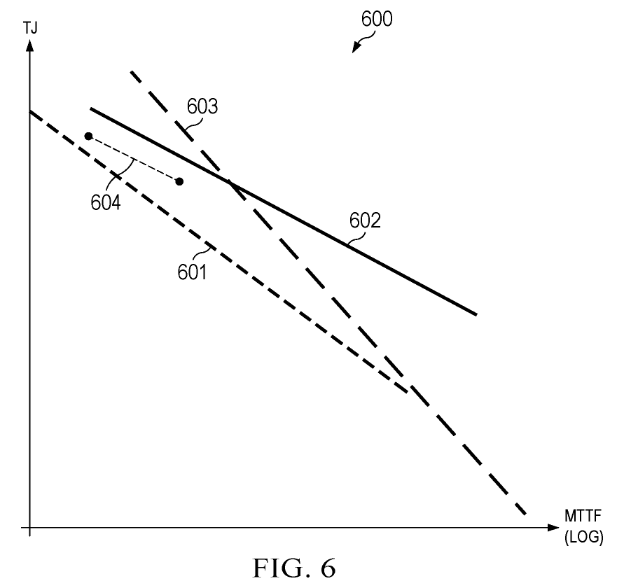

Referring now to FIGS. 3 and 6, the graph 300 in FIG. 3 also illustrates three example data points 311, 312 and 313 generally along the load line 302. As previously discussed, DC accelerated life testing can be implemented at a fixed transistor bias point to allow the use of low cost test equipment. However, DC accelerated life testing does not provide high confidence in estimating device lifetime with respect to all possible failure mechanisms associated with a transistor. FIG. 6 shows a graph 600 of failure time (e.g., MTTF) as a function of temperature (e.g., junction temperature TJ) for different transistor failure (e.g., degradation) mechanisms shown as curves 601-604 (e.g., Arrhenius plots). The first curve 601 in this example represents an example gallium nitride transistor surface pitting failure mechanism for the transistor T, and a second curve 602 represents a hot electron failure mechanism. The third curve 603 in FIG. 6 represents an electron trapping failure mechanism, and the fourth curve 604 shows example comparative data obtained by two RF accelerated life tests performed using the same form and factor DUT 202.

As seen in the graph 600, different failure mechanisms of an example transistor T may have different Arrhenius plots and time-temperature relationships. In addition, it is noted that certain failure mechanisms represented by the curves 601-603 may avoid accurate characterization using only DC accelerated life testing techniques (e.g., testing at only one of the example points 311, 312 or 313 in FIG. 3 above). Consequently, the described low frequency accelerated life testing method 100 and system 200 advantageously provide the cost and complexity benefits previously associated with DC accelerated life testing, while incorporating testing along the load line for improved accuracy and assessment of multiple transistor failure mechanisms, and also allowing relatively quick, cost effective testing using low frequency sweeps of the load line 302, 304.

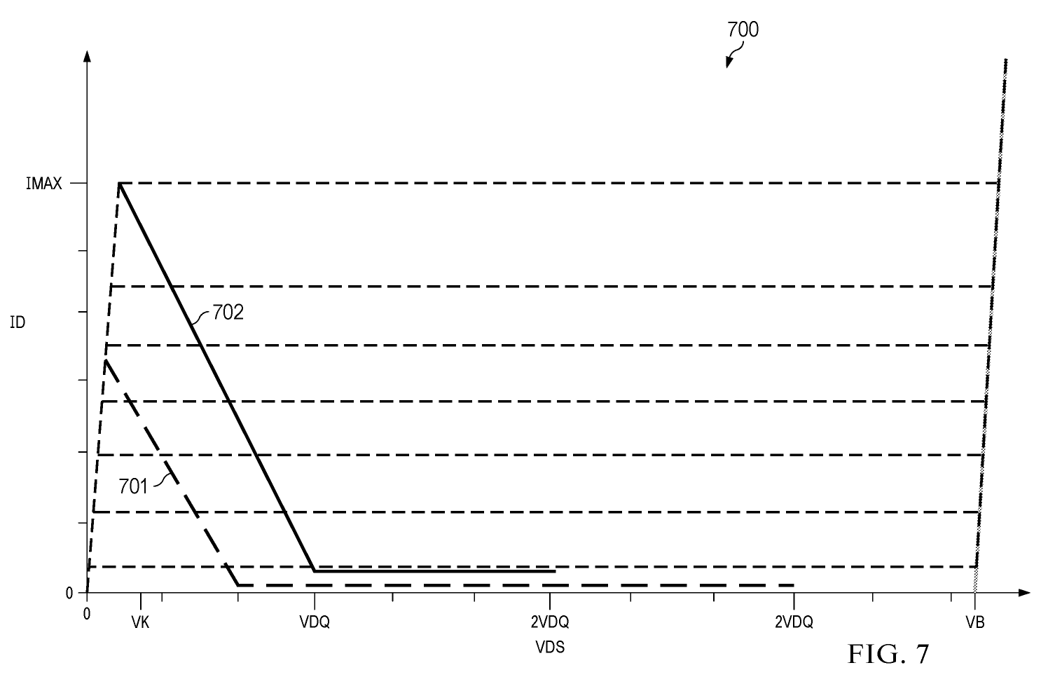

Referring also to FIG. 7, the example load lines 302, 304 used in low-frequency sweep testing in the method 100 can be derived from empirical and/or theoretical data based on a given transistor and electronic device design. FIG. 7 shows a graph 700 of efficiency and peak power load lines for a class B Doherty power amplifier DUT 202. The graph 700 includes a theoretical constant power dissipation load line 702 corresponding to maximum rated operating conditions of the class B power amplifier DUT 202. The graph 700 also includes a lower load line 701 that corresponds to a maximum efficiency operating condition of a class B Doherty power amplifier DUT 202. In operation of the DUT 202 in field use, the recommended usage conditions are between the load line curve 701 and 702 in order to preferentially achieve high efficiency without exceeding maximum rated operating conditions. With respect to accelerated life testing using the above-described low frequency ALT techniques and systems, the example load lines 302 and 304 (FIG. 3) can be advantageously selected to generally correspond to the second curve 702 for a given DUT design, for example, in order to facilitate accelerated life testing in an expeditious, cost-effective manner using a load line 302, 304 that provides substantially constant power dissipation of the tested DUT 202 during accelerated life testing.

While various examples of the present disclosure have been described above, it should be understood that they have been presented by way of example only and not limitation. Numerous changes to the disclosed examples can be made in accordance with the disclosure herein without departing from the spirit or scope of the disclosure. Thus, the breadth and scope of the present description should not be limited by any of the above described examples. Rather, the scope of the disclosure should be defined in accordance with the following claims and their equivalents. Modifications are possible in the described examples, and other implementations are possible, within the scope of the claims.

What is claimed is:

1. A test method, comprising:
heating a first device under test with a first transistor to a first temperature;
sweeping a transistor bias point of the first transistor along a load line at a sweep frequency that is less than an operating frequency of the first device under test for multiple cycles at the first temperature until a first time at which a transistor performance parameter reaches a threshold;
heating a second device under test with a second transistor to a different second temperature;
sweeping a transistor bias point of the second transistor along the load line at the sweep frequency for multiple cycles at the second temperature until a second time at which the transistor performance parameter reaches the threshold; and
determining a transistor lifetime based on the first and second times.

2. The test method of claim 1, wherein the sweep frequency is 1 kHz or more and 1 MHz or less.

3. The test method of claim 1, wherein the sweep frequency is less than 0.01 times the operating frequency of the first device under test.

4. The test method of claim 1, wherein the load line has a staircase shape.

5. The test method of claim 4, wherein sweeping the transistor bias point includes adjusting a gate voltage of the transistor and adjusting a drain voltage of the transistor.

6. The test method of claim 4, wherein the load line represents a transistor drain current as a function of a transistor drain voltage and a transistor gate voltage.

7. The test method of claim 4, wherein the load line provides a constant power dissipation for the transistor.

8. The test method of claim 1, wherein the load line represents a class of an amplifier circuit of the device under test.

9. The test method of claim 1, wherein sweeping the transistor bias point includes adjusting a gate voltage of the transistor and adjusting a drain voltage of the transistor.

10. The test method of claim 1, wherein the load line represents a transistor drain current as a function of a transistor drain voltage and a transistor gate voltage.

11. The test method of claim 1, wherein the load line provides a constant power dissipation for the transistor.

12. The test method of claim 1, wherein the transistor operating parameter is a transistor drain current.

13. The test method of claim 8, wherein the transistor is a gallium nitride transistor.

14. A system, comprising:
a first voltage source with a first voltage output electrically coupled to a transistor gate of a device under test installed in a socket;
a second voltage source with a second voltage output electrically coupled to a transistor drain of the device under test;
a heat source operatively coupled to provide heat to the socket to heat the device under test; and
a controller configured to control the heat source to heat a device under test with a transistor to a target temperature, and to control the first and second voltage sources to sweep a transistor bias point of the first transistor along a load line at a sweep frequency that is less than an operating frequency of the device under test for multiple cycles at the target temperature until a transistor performance parameter reaches a threshold.

15. The system of claim 14, wherein the sweep frequency is 1 kHz or more and 1 MHz or less.

16. The system of claim 14, wherein the sweep frequency is less than 0.01 times the operating frequency of the first device under test.

17. The system of claim 14, wherein the load line has a staircase shape.

18. The system of claim 14, wherein the controller is configured to sweep the transistor bias point by controlling the first voltage source to adjust a gate voltage of the transistor and by controlling the second voltage source to adjust a drain voltage of the transistor.

19. The system claim 14, wherein the load line provides a constant power dissipation for the transistor.

20. The system of claim 14, wherein the transistor operating parameter is a transistor drain current.
